(19) United States
(12) Patent Application Publication
(10) Pub. No.: US 2019/0386072 A1
(43) Pub. Date: Dec. 19, 2019

(54) PIXEL ARRANGEMENT STRUCTURE AND METHOD FOR MANUFACTURING THE SAME

(71) Applicant: WUHAN CHINA STAR OPTOELECTRONICS SEMICONDUCTOR DISPLAY TECHNOLOGY CO., LTD., Wuhan, Hebei (CN)

(72) Inventor: CHAO XU, Shenzhen (CN)

(21) Appl. No.: 15/736,140

(22) PCT Filed: Oct. 21, 2017
(86) PCT No.: PCT/CN2017/107180

§ 371 Date: Dec. 13, 2017

(30) Foreign Application Priority Data
Sep. 14, 2017 (CN) 201710827263.3

(51) Int. Cl. H01L 27/32; H01L 51/56

(52) U.S. Cl. CPC H01L 27/3213; H01L 2251/558; H01L 27/3202; H01L 51/56

(57) ABSTRACT

A pixel arrangement structure is provided. The pixel arrangement structure may include multiple pixels arranged as an array with multiple rows and columns. The multiple pixels may each include a red sub-pixel, a green sub-pixel, a blue sub-pixel and a yellow sub-pixel. The red sub-pixel, the yellow sub-pixel and the green sub-pixel may be arranged in parallel and located at one side of the blue sub-pixel. When implemented on an OLED display, the pixel arrangement structure of the present disclosure may broaden the display gamut of the OLED display and improve its resolution.

### CROSS-REFERENCE TO RELATED APPLICATIONS

The present application is a 35 U.S.C. § 371 National Phase conversion of International (PCT) Patent Application No. PCT/CN2017/107180, filed on Oct. 21, 2017, which claims foreign priority of Chinese Patent Application No. 201710827263.3, filed on Sep. 14, 2017 in the State Intellectual Property Office of China, the contents of all of which are hereby incorporated by reference.

### TECHNICAL FIELD

The present disclosure generally relates to the display technique field, and in particular to a pixel arrangement structure and a method for manufacturing the same.

### BACKGROUND

Organic Light-Emitting Diode (OLED) display have several advantages such as high brightness, high response speed, low consumption and high flexibility. It is considered to be an important aspect of the next generation display technique. Compared with a TFT-LCD, an OLED display is advantageously ultrathin, transparent, flexible and foldable.

At the moment, an OLED display is still manufactured by applying vapor deposition technique. A fine metal mask (FMM) is required for manufacturing pixels with vapor deposition technique.

### SUMMARY

The present disclosure aims to provide a pixel arrangement structure and a method for manufacturing the same. When the pixel arrangement structure is implemented on an OLED display, the display gamut may be effectively improved such that an OLED display with ultrahigh resolution may be acquired.

To solve the above mentioned problem, a technical scheme adopted by the present disclosure is to provide a pixel arrangement structure comprising a plurality of pixels arranged as an array with a plurality of rows and columns; the plurality of pixels each comprising a red sub-pixel, a green sub-pixel, a blue sub-pixel and a yellow sub-pixel; wherein, the red sub-pixel, the yellow sub-pixel and the green sub-pixel are arranged in parallel and located at one side of the blue sub-pixel; an area of the blue sub-pixel is greater than or equal to a sum of that of the red sub-pixel, the green sub-pixel and the yellow sub-pixel.

To solve the above-mentioned problem, another technical scheme adopted by the present disclosure is to provide a pixel arrangement structure comprising a plurality of pixels arranged as an array with a plurality of rows and columns; the plurality of pixels each comprising a red sub-pixel, a green sub-pixel, a blue sub-pixel and a yellow sub-pixel; wherein, the red sub-pixel, the yellow sub-pixel and the green sub-pixel are arranged in parallel and located at one side of the blue sub-pixel.

To solve the above-mentioned problem, another technical scheme adopted by the present disclosure is to provide a method for manufacturing a pixel arrangement structure, comprising: providing a substrate; forming a red sub-pixel on the substrate; forming a green sub-pixel on the substrate, wherein a yellow sub-pixel is formed by an overlapping portion of the red sub-pixel and the green sub-pixel; and forming a blue sub-pixel on the substrate.

The pixel arrangement structure of the present disclosure includes a plurality of pixels arranged as an array with a plurality of rows and columns. The plurality of pixels each includes a red sub-pixel, a green sub-pixel, a blue sub-pixel and a yellow sub-pixel, wherein the red sub-pixel, the yellow sub-pixel, the green sub-pixel are arranged in parallel and located at one side of the blue sub-pixel. The present disclosure replaces the three-color pixel of a red sub-pixel, a green sub-pixel and a blue sub-pixel by a four-color pixel of a red sub-pixel, a green sub-pixel, a blue sub-pixel and a yellow sub-pixel. Therefore, when implemented on an OLED display, the pixel arrangement structure of the present disclosure may broaden the display gamut of the OLED display and improve its resolution.

### BRIEF DESCRIPTION OF THE DRAWINGS

FIG. 1 is a diagram depicting the pixel arrangement of the pixel arrangement structure according to an embodiment of the present disclosure.

FIG. 2 is a diagram depicting the pixel arrangement of the pixel arrangement structure according to another embodiment of the present disclosure.

FIG. 3 is a diagram depicting the pixel arrangement of the pixel arrangement structure according to another embodiment of the present disclosure.

FIG. 4 is a flowchart of the method for manufacturing the pixel arrangement structure according to an embodiment of the present disclosure.

### DETAILED DESCRIPTION

The disclosure will now be described in detail with reference to the accompanying drawings and examples.

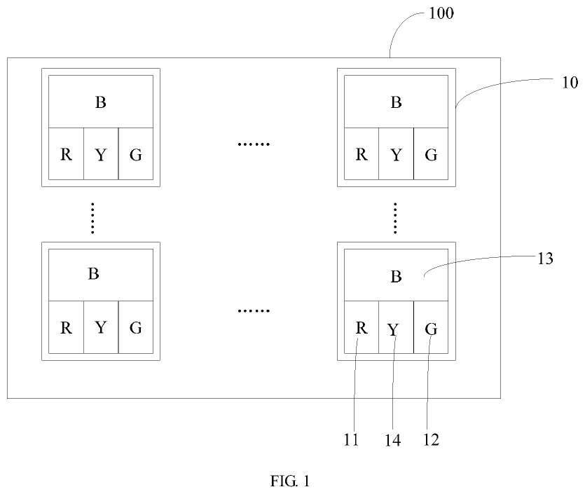

Referring to FIG. 1, FIG. 1 is a diagram depicting the pixel arrangement of the pixel arrangement structure 100 according to an embodiment of the present disclosure. The pixel arrangement structure 100 of the present disclosure may include multiple pixels 10 arranged as an array with multiple rows and columns. The multiple pixels 10 may each include a red sub-pixel 11, a green sub-pixel 12, a blue sub-pixel 13 and a yellow sub-pixel 14. The red sub-pixel 11, the yellow sub-pixel 14 and the green sub-pixel 12 may be arranged in parallel and located at one side of the blue sub-pixel 13.

The red sub-pixel 11 may include a red light emitting material. The green sub-pixel 12 may include a green light emitting material. The blue sub-pixel 13 may include a blue light emitting material. The yellow sub-pixel 14 may be a compound of the red sub-pixel 11 and the green sub-pixel 12, i.e., a compound of the red light emitting material and the green light emitting material.

In this embodiment, the area of the blue sub-pixel 13 may be greater than the sum of the areas of the red sub-pixel 11, the green sub-pixel 12 and the yellow sub-pixel 14. Alternatively, the area of the blue sub-pixel 13 may be equal to the sum of the areas of the red sub-pixel 11, the green sub-pixel 12 and the yellow sub-pixel 14.

It should be understood that, since the light emitting material of the blue sub-pixel 13 has a lower light emitting efficiency than that of the red sub-pixel 11, the green sub-pixel 12 and the yellow sub-pixel 14, the area of the blue sub-pixel 13 should be greater than that of the red sub-pixel 11, the green sub-pixel 12 and the yellow sub-pixel 14 so as to substantially equalize the brightness of emitting light of each sub-pixel.

In this embodiment, the areas of the red sub-pixel 11, the yellow sub-pixel 14 and the green sub-pixel 12 may be substantially the same.

In this embodiment, the blue sub-pixel 13 may be arranged in a longitudinal direction. The red sub-pixel 11, the yellow sub-pixel 14 and the green sub-pixel 12 may be arranged in parallel along a long side of the blue sub-pixel 13, wherein the length of the blue sub-pixel 13 arranged in the longitudinal direction may be equal to the sum of the widths of the red sub-pixel 11, the yellow sub-pixel 14 and the green sub-pixel 12 arranged in parallel.

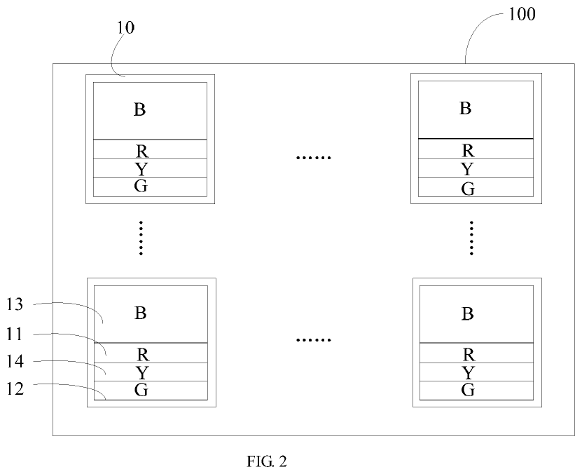

In one embodiment, referring to FIG. 2, the blue sub-pixel 13 may be arranged in a longitudinal direction. The red sub-pixel 11, the yellow sub-pixel 14 and the green sub-pixel 12 may be arranged in parallel along a long side of the blue sub-pixel 13, wherein the length of the blue sub-pixel 13 arranged in the longitudinal direction may be equal to that of the red sub-pixel 11, the yellow sub-pixel 14 and the green sub-pixel 12. The width of the blue sub-pixel 13 arranged in the longitudinal direction may be equal to the sum of the widths of the red sub-pixel 11, the yellow sub-pixel 14 and the green sub-pixel 12 arranged in parallel.

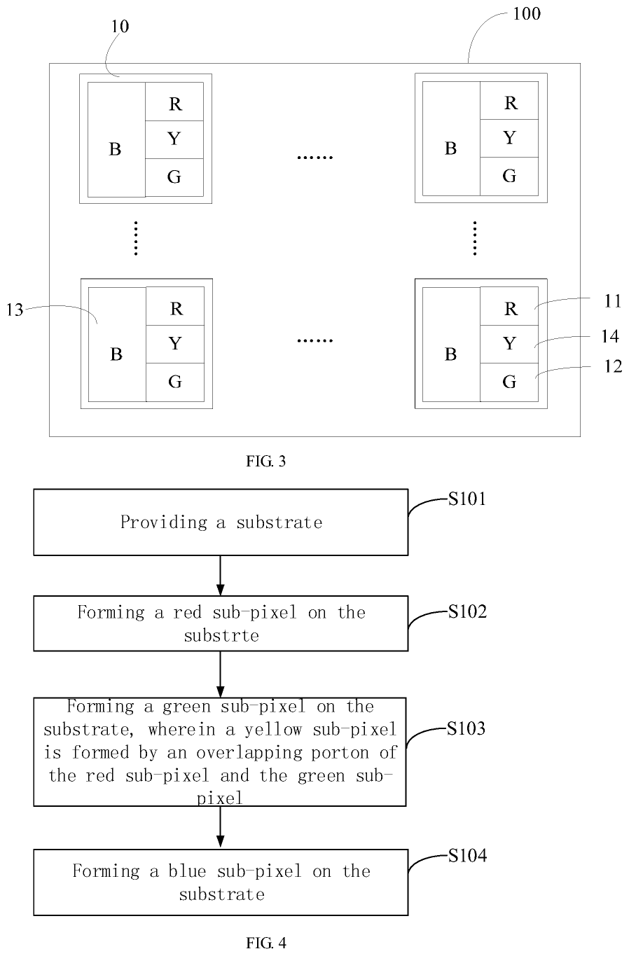

In another embodiment, referring to FIG. 3, the blue sub-pixel 13 may be arranged in a transversal direction. The red sub-pixel 11, the yellow sub-pixel 14 and the green sub-pixel 12 may be arranged in parallel along a long side of the blue sub-pixel 13, wherein the length of the blue sub-pixel 13 arranged in the transversal direction may be equal to the sum of the widths of the red sub-pixel 11, the yellow sub-pixel 14 and the green sub-pixel 12.

In other embodiments, the arrangement of the blue sub-pixel 13, the red sub-pixel 11, the yellow sub-pixel 14 and the green sub-pixel 12 may be accordingly adjusted if necessary, and should not be taken as a limit of the scope of the present disclosure.

The red sub-pixel 11, the green sub-pixel 12, the blue sub-pixel 13 and the yellow sub-pixel 14 may each have a thickness ranged from 10 nm to 100 nm. More specifically, the red sub-pixel 11, the green sub-pixel 12, the blue sub-pixel 13 and the yellow sub-pixel 14 may each have a thickness ranged from 10 nm to 80 nm, such as 30 nm, 50 nm or 70 nm etc.

The pixel arrangement structure 100 of the present disclosure may include multiple pixels arranged as an array with multiple rows and columns, and the multiple pixels may each include a red sub-pixel 11, a green sub pixel 12, a blue sub-pixel 13 and a yellow sub-pixel 14, wherein the red sub-pixel 11, the yellow sub pixel 14 and the green sub-pixel 12 may be arranged in parallel and located at one side of the blue sub-pixel 13. The present disclosure may replace a three-color pixel of a red sub-pixel, a green sub-pixel and a blue sub-pixel by a four-color pixel of a red sub-pixel, a green sub-pixel, a blue sub-pixel and a yellow sub-pixel. Therefore, when implemented on an OLED display, the pixel arrangement structure of the present disclosure may broaden the display gamut of the OLED display and improve its resolution.

Referring to FIG. 4, a method for manufacturing the pixel arrangement structure may be provided according to one embodiment of the present disclosure. The method may include the following blocks.

At S101, providing a substrate.

In one embodiment, the substrate may be a glass substrate or a flexible substrate.

At S102, forming a red sub-pixel on the substrate.

The red sub-pixel may include a red light emitting material.

In this embodiment, the red sub-pixel may be formed by vapor deposition.

At S103, forming a green sub-pixel on the substrate, wherein a yellow sub-pixel is formed by an overlapping portion of the red sub-pixel and the green sub-pixel.

The green sub-pixel may include a green light emitting material. The yellow sub-pixel may be a compound of the red light emitting material and the green light emitting material.

In this embodiment, the green sub-pixel may be formed by vapor deposition.

At S104, forming a blue sub-pixel on the substrate.

The blue sub-pixel may include a blue light emitting material.

In this embodiment, the blue sub-pixel may be formed by vapor deposition.

In this embodiment, the area of the blue sub-pixel may be greater than the sum of the areas of the red sub-pixel, the green sub-pixel and the yellow sub-pixel. Alternatively, the area of the blue sub-pixel may be equal to the sum of the areas of the red sub-pixel, the green sub-pixel and the yellow sub-pixel.

It should be understood that, since the light emitting material of the blue sub-pixel has a lower light emitting efficiency than that of the red sub-pixel, the green sub-pixel and the yellow sub-pixel, the area of the blue sub-pixel should be greater than that of the red sub-pixel, the green sub-pixel and the yellow sub-pixel so as to substantially equalize the brightness of these sub-pixels.

In this embodiment, the areas of the red sub-pixel, the yellow sub-pixel and the green sub-pixel may be substantially the same.

In this embodiment, the blue sub-pixel may be arranged in a longitudinal direction. The red sub-pixel, the yellow sub-pixel and the green sub-pixel may be arranged in parallel along a long side of the blue sub-pixel, wherein the length of the blue sub-pixel arranged in the longitudinal direction is equal to the sum of the widths of the red sub-pixel, the yellow sub-pixel and the green sub-pixel arranged in parallel.

In another embodiment, the blue sub-pixel may be arranged in a longitudinal direction. The red sub-pixel, the yellow sub-pixel and the green sub-pixel may be arranged in parallel along a long side of the blue sub-pixel, wherein the length of the blue sub-pixel arranged in the longitudinal direction may be equal to that of the red sub-pixel, the yellow sub-pixel and the green sub-pixel. The width of the blue sub-pixel arranged in the longitudinal direction may be equal to the sum of the widths of the red sub-pixel, the yellow sub-pixel and the green sub-pixel arranged in parallel.

In another embodiment, the blue sub-pixel may be arranged in a transversal direction. The red sub-pixel, the yellow sub-pixel and the green sub-pixel may be arranged in parallel along a long side of the blue sub-pixel, wherein the length of the blue sub-pixel arranged in the transversal direction may be equal to the sum of the widths of the red sub-pixel, the yellow sub-pixel and the green sub-pixel.

In other embodiments, the arrangement of the blue sub-pixel, the red sub-pixel, the yellow sub-pixel and the green sub-pixel may be accordingly adjusted if necessary, and should not be taken as a limit of the scope of the present disclosure.

The red sub-pixel, the green sub-pixel, the blue sub-pixel and the yellow sub-pixel may each have a thickness ranged from 10 nm to 100 nm. More specifically, the red sub-pixel, the green sub-pixel, the blue sub-pixel and the yellow sub-pixel may each have a thickness ranged from 10 nm to 80 nm, such as 30 nm, 50 nm or 70 nm etc.

In one embodiment, S103 may be executed before S102, which is to say, the green sub-pixel may be firstly formed on the substrate by vapor deposition, then the red sub-pixel may be formed on the substrate by vapor deposition, wherein a yellow sub-pixel is formed by an overlapping portion of the red sub-pixel and the green sub-pixel.

In one embodiment, S104 may be executed before S102 and S103, which is to say, the blue sub-pixel may firstly be formed on the substrate by vapor deposition, then the green sub-pixel or the red sub-pixel may be formed on the substrate by vapor deposition, at last the other sub-pixel may be formed on the substrate by vapor deposition, wherein a yellow sub-pixel is formed by an overlapping portion of the red sub-pixel and the green sub-pixel.

Different from prior art, the method for manufacturing the pixel arrangement structure according to this embodiment of the present disclosure may include the following blocks: providing a substrate; forming a red sub-pixel on the substrate; forming a green sub-pixel on the substrate, wherein a yellow sub-pixel is formed by an overlapping portion of the green sub-pixel and the red sub-pixel; forming a blue sub-pixel on the substrate. By overlapping partially the green sub-pixel and the red sub-pixel, the yellow sub-pixel may be acquired, i.e., red light emitted by the red sub-pixel and green light emitted by the green sub-pixel constitute yellow light. Therefore, the yellow sub-pixel may be manufactured at the same time as the red sub-pixel and the green sub-pixel, which may simplify the manufacturing process. Furthermore, during the manufacturing process, without changing the size of the through hole of the FMM utilized, a three-color pixel of a red sub-pixel, a green sub-pixel and a blue sub-pixel may be replaced by a four-color pixel of a red sub-pixel, a green sub-pixel, a blue sub-pixel and a yellow sub-pixel. Therefore, when implemented on an OLED display, the pixel arrangement structure of the present disclosure may broaden the display gamut of the OLED display and improve its resolution.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

1-4. (canceled)

5. A pixel arrangement structure, comprising a plurality of pixels arranged as an array with a plurality of rows and columns; the plurality of pixels each comprising a red sub-pixel, a green sub-pixel, a blue sub-pixel and a yellow sub-pixel;
wherein, the red sub-pixel, the yellow sub-pixel and the green sub-pixel are arranged in parallel and located on a first side of the blue sub-pixel.

6. The pixel arrangement structure of claim 5, wherein an area of the blue sub-pixel is larger than a sum of areas of the red sub-pixel, the green sub-pixel and the yellow sub-pixel.

7. The pixel arrangement structure of claim 5, wherein an area of the blue sub-pixel is substantially equal to a sum of areas of the red sub-pixel, the green sub-pixel and the yellow sub-pixel.

8. The pixel arrangement structure of claim 5, wherein
the first side of the blue sub-pixel having a length and defining a first direction; the red sub-pixel, the yellow sub-pixel and the green sub-pixel are arranged in parallel along the first direction on said first side of the blue sub-pixel;
wherein the length of the first side of the blue sub-pixel is equal to a sum of lengths of the red sub-pixel, the yellow sub-pixel and the green sub-pixel along the first direction.

9. The pixel arrangement structure of claim 5, wherein the red sub-pixel, the green sub-pixel, the blue sub-pixel and the yellow sub-pixel each has a thickness ranging from 10 nm to 100 nm.

10. The pixel arrangement structure of claim 5, wherein areas of the red sub-pixel, the yellow sub-pixel and the green sub-pixel are substantially same.

11. A method for manufacturing a pixel arrangement structure, comprising:
providing a substrate;
forming a red sub-pixel on the substrate;
forming a green sub-pixel on the substrate, wherein a yellow sub-pixel is formed by an overlapping portion of the red sub-pixel and the green sub-pixel; and
forming a blue sub-pixel on the substrate, each of said sub-pixels defining an area.

12. The method of claim 11, wherein an area of the blue sub-pixel is larger than a sum of areas of the red sub-pixel, the green sub-pixel and the yellow sub-pixel.

13. The method of claim 11, wherein
a first side of the blue sub-pixel having a length and defining a first direction; the red sub-pixel, the yellow sub-pixel and the green sub-pixel are arranged in parallel along the first direction on said first side of the blue sub-pixel;
wherein the length of the first side of the blue sub-pixel is equal to a sum of lengths of the red sub-pixel, the yellow sub-pixel and the green sub-pixel along the first direction.

14. The method of claim 11, the red sub-pixel, the green sub-pixel, the blue sub-pixel and the yellow sub-pixel are formed by vapor deposition.

15. The method of claim 11, wherein an area of the blue sub-pixel is substantially equal to a sum of areas of the red sub-pixel, the green sub-pixel and the yellow sub-pixel.

16. The method of claim 11, wherein areas of the red sub-pixel, the yellow sub-pixel and the green sub-pixel are substantially same.

17. The method of claim 11, wherein the red sub-pixel, the green sub-pixel, the blue sub-pixel and the yellow sub-pixel each has a thickness ranging from 10 nm to 100 nm.

18. A pixel arrangement structure, comprising a plurality of pixels arranged as an array;
wherein each of the pixels comprises a blue sub-pixel, a red sub-pixel and a green sub-pixel;
wherein the red sub-pixel and the green sub-pixel have an overlapping portion and the overlapping portion forms a yellow sub-pixel.

19. The pixel arrangement structure of claim 18, wherein an area of the blue sub-pixel is larger than a sum of areas of the red sub-pixel, the green sub-pixel and the yellow sub-pixel.

20. The pixel arrangement structure of claim 18, wherein an area of the blue sub-pixel is substantially equal to a sum of areas of the red sub-pixel, the green sub-pixel and the yellow sub-pixel.

21. The pixel arrangement structure of claim 18, wherein
the blue sub-pixel has a first side defining a first direction; the red sub-pixel, the yellow sub-pixel and the green sub-pixel are arranged in parallel along the first side of the blue sub-pixel;
wherein a length of the blue sub-pixel along the first direction is equal to a sum of lengths of the red sub-pixel, the yellow sub-pixel and the green sub-pixel along the first direction.

22. The pixel arrangement structure of claim 18, wherein
the blue sub-pixel has a first side defining a first direction; the red sub-pixel, the yellow sub-pixel and the green sub-pixel are arranged in parallel along the first side of the blue sub-pixel;
wherein a first length of the blue sub-pixel along the first direction is substantially equal to lengths of the red sub-pixel, the yellow sub-pixel and the green sub-pixel along the first direction, and a second length of the blue sub-pixel along a second direction perpendicular to the first direction is equal to a sum of widths of the red sub-pixel, the yellow sub-pixel and the green sub-pixel along the second direction.

23. The pixel arrangement structure of claim 18, wherein the red sub-pixel, the green sub-pixel, the blue sub-pixel and the yellow sub-pixel each has a thickness ranging from 10 nm to 100 nm.

24. The pixel arrangement structure of claim 18, wherein areas of the red sub-pixel, the yellow sub-pixel and the green sub-pixel are substantially same.
